(19) United States
(12) Patent Application Publication
(10) Pub. No.: US 2012/0073783 A1
(43) Pub. Date: Mar. 29, 2012

(54) HEAT EXCHANGER FOR DATA CENTER

(75) Inventor: Rajesh M. Nair, Nashua, NH (US)

(73) Assignee: Degree Controls, Inc., Milford, NH (US)

(21) Appl. No.: 13/246,455

(22) Filed: Sep. 27, 2011

Related U.S. Application Data
(60) Provisional application No. 61/386,644, filed on Sep. 27, 2010.

(51) Int. Cl. H05K 7/20

(52) U.S. Cl. 165/53

(57) ABSTRACT

A data center room is adapted to include electronic equipment supported by a floor. At least one wall of the room is formed as a heat exchanger that conducts heat generated by the electronic equipment outside of the room. An airflow path is formed across the wall to provide outside air to move heat away from the ceiling.

### BACKGROUND

Data centers generate tremendous amounts of heat which must be removed to ensure the integrity of electronic equipment in the data center. Many data centers have significant air conditioning equipment the provides cool air to help remove the heat. As circuit densities keep increasing, the production of heat by equipment also increases. This further drives the need for air conditioning equipment and the commensurate increase in cooling costs.

### BRIEF DESCRIPTION OF THE DRAWINGS

FIG. 1 is a block diagram of a data center including a heat exchanger according to an example embodiment.

FIG. 2 is a flowchart illustrating a method of controlling airflow over the heat exchanger of FIG. 1.

FIG. 3 is a block diagram of a computer system to implement methods according to an example embodiment.

FIG. 4 is a block diagram of a containerized data center room on a flatbed truck according to an example embodiment.

FIG. 5A is a block diagram illustrating electrical connection of two container in a scalable modular form according to an example embodiment.

FIG. 5B is a block diagram top view illustrating multiple containers connected side by side and end to end according to an example embodiment.

FIG. 5C is a block diagram side view illustrating multiple containers in a stacked relationship according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

The functions or algorithms described herein may be implemented in software or a combination of software and human implemented procedures in one embodiment. The software may consist of computer executable instructions stored on computer readable media such as memory or other type of storage devices. Further, such functions correspond to modules, which are software stored on a storage device, hardware, firmware or any combination thereof. Multiple functions may be performed in one or more modules as desired, and the embodiments described are merely examples. The software may be executed on a digital signal processor, ASIC, microprocessor, or other type of processor operating on a computer system, such as a personal computer, server or other computer system.

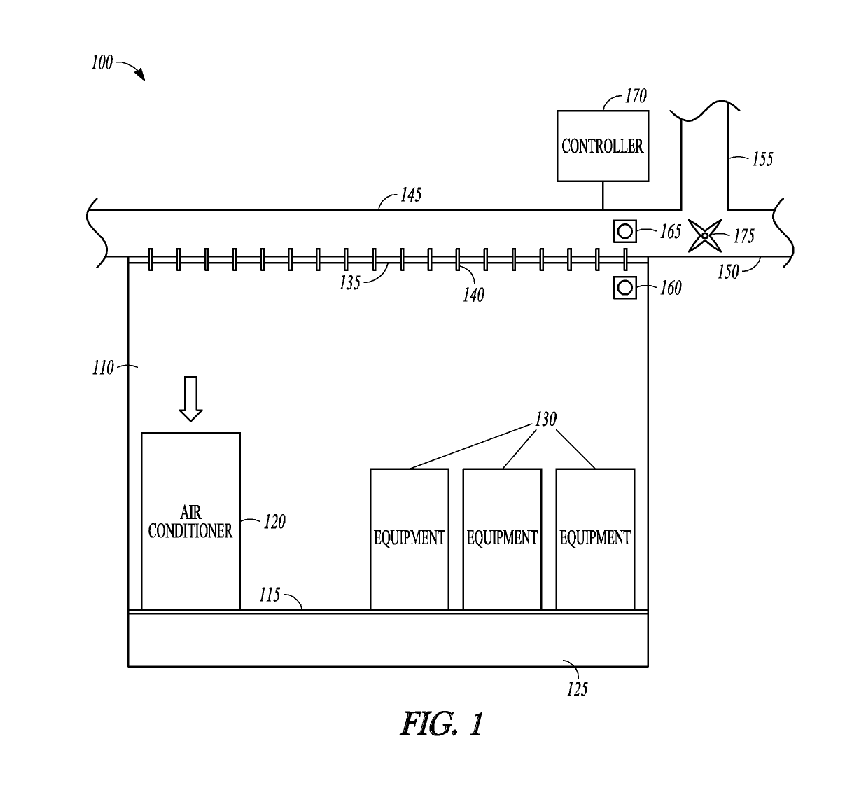

FIG. 1 is a block diagram of an example data center 100. The data center 100 includes a room 110 having a raised floor 115 in one embodiment. The raised floor allows for the inclusion of air conditioning equipment 120 beneath the raised floor, or supported by the raised floor as illustrated, to provide cooled air via space under the floor 125 to electronic equipment 130 supported by the raised floor 115. In one embodiment, ducts may be used under the floor 115. The ducts, if used, should be sized to minimize resistance to the flow of air. Return air is indicated by the arrow at the top of air conditioning equipment 120.

In further embodiments, the air conditioning equipment may be located elsewhere, with cool air being provided to ducts or open space 125 to cool the equipment 130. Some data centers may not have a raised floor. In such a solid floor embodiment, cold air inlets and hot air return may be from the top of such rooms, or other convenient locations, with ducting as needed to and from the air conditioning equipment. Equipment 130 may be arranged in an open or closed isle configuration in various embodiments.

The room 110 also includes a wall 135 that is formed as a heat exchanger to conduct heat generated by the electronic equipment away from room 110. In one embodiment, at least one wall 135, such as a ceiling of the room is formed of corrugated metal or other heat conducting material and may include one or more fins 140 to better conduct heat outside of room 110. The wall 135 may form a seal with respect to air within the room 110 such that the air in room 110 is not reduced in quality from air on the other side of ceiling 135. In one embodiment, the wall 135 is formed of ceiling tiles of a desired heat conductive material.

In one embodiment, an airflow path 145 extends above and across the heat exchanger ceiling 135 opposite room 110 to provide outside or ambient cooler air via a path 150 to move heat away from the wall 135. In some climates, the outside air may be significantly cooler than air inside the room. To prevent condensation, the airflow path 145 may include a further airflow path or inlet 155 to provide warmer air to mix with the outside air from path 150.

In one embodiment, sensors 160 and 165 may be used to ensure that the temperature of the wall 135 does not get below the dew point of air within room 110. Sensor or sensors 160 may be disposed within the room 110 to measure the dew point of air within room 110. Sensor 165 may be disposed in airflow path 145, or thermally proximate wall 135 to measure the temperature of air or the temperature of the ceiling to ensure that the temperature of the ceiling within room 110 does not reach the dew point of air within room 110. In one embodiment, a controller 170 is coupled to a mixer 175 positioned to mix airflow from paths 155 and 150 to control the temperature of the wall 135. The controller may be hardwired to mixer 175 and the sensors 160, 165, or connected wireless in various embodiments. The heat exchanger is adapted to reduce a cooling load on the air conditioning equipment.

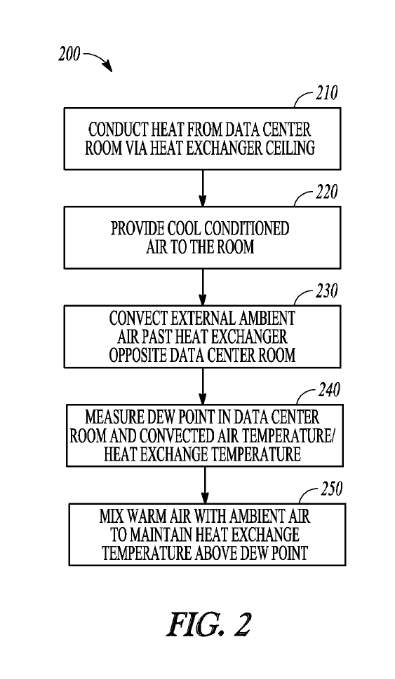

FIG. 2 is a flowchart illustrating a method 200 of controlling airflow over the heat exchanger wall 135 of FIG. 1. Method 200 includes conducting heat outside a data center room having heat generating electronic equipment via a heat exchanger ceiling of the room at 210. At 220, conditioned cool air is provided to the room to help cool the equipment. At 230, ambient cool air is convected or moved past the heat exchanger ceiling outside the room to remove heat from the room and reduce a need for conditioned cool air.

In one embodiment, method 200 also includes measuring the dew point of air in the data center room, as well as the temperature of the air moving past the heat exchanger wall, or alternatively, the ceiling temperature at 240. This information is then used to mix warm air with the ambient air at 250 to maintain the heat exchanger ceiling temperature above the dew point in the room. This prevents condensation forming on the ceiling and dripping onto the electronic equipment, while still optimally reducing the load on air conditioning equipment.

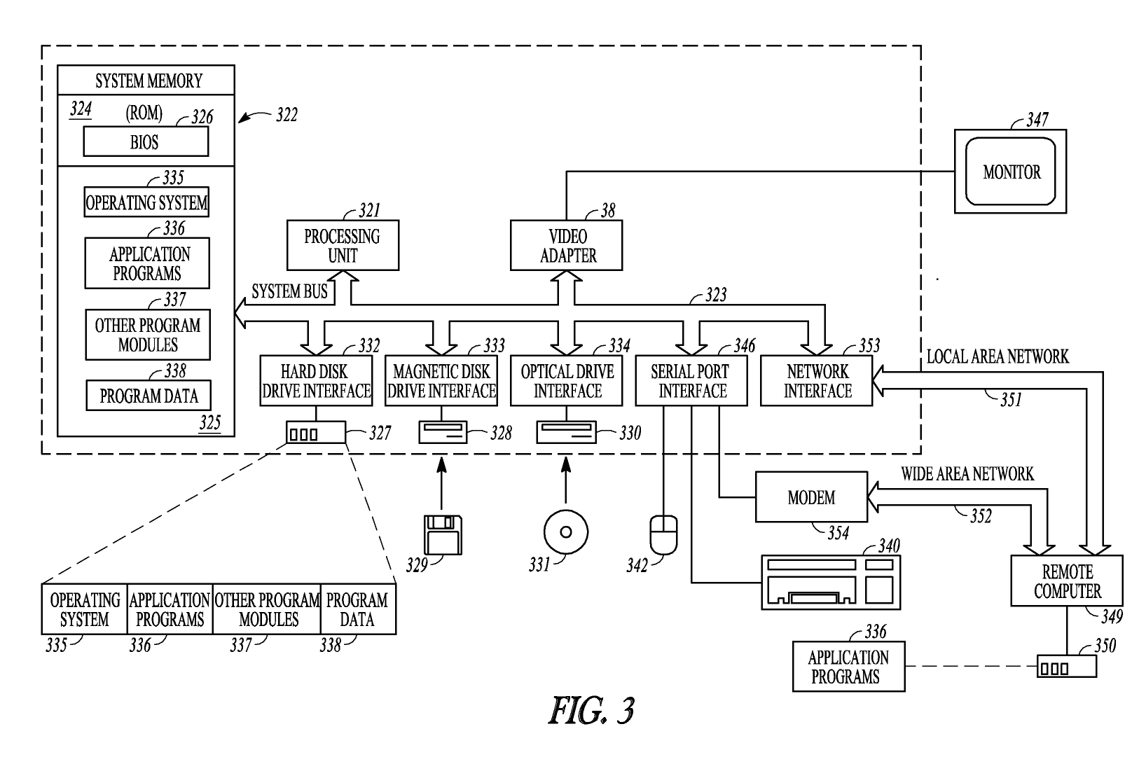

In the embodiment shown in FIG. 3, a hardware and operating environment is provided that is applicable to any of the servers and/or remote clients shown in the other Figures.

As shown in FIG. 3, one embodiment of the hardware and operating environment includes a general purpose computing device in the form of a computer 300 (e.g., a personal computer, workstation, or server), including one or more processing units 321, a system memory 322, and a system bus 323 that operatively couples various system components including the system memory 322 to the processing unit 321. There may be only one or there may be more than one processing unit 321, such that the processor of computer 300 comprises a single central-processing unit (CPU), or a plurality of processing units, commonly referred to as a multiprocessor or parallel-processor environment. In various embodiments, computer 300 is a conventional computer, a distributed computer, or any other type of computer.

The system bus 323 can be any of several types of bus structures including a memory bus or memory controller, a peripheral bus, and a local bus using any of a variety of bus architectures. The system memory can also be referred to as simply the memory, and, in some embodiments, includes read-only memory (ROM) 324 and random-access memory (RAM) 325. A basic input/output system (BIOS) program 326, containing the basic routines that help to transfer information between elements within the computer 300, such as during start-up, may be stored in ROM 324. The computer 300 further includes a hard disk drive 327 for reading from and writing to a hard disk, not shown, a magnetic disk drive 328 for reading from or writing to a removable magnetic disk 329, and an optical disk drive 330 for reading from or writing to a removable optical disk 331 such as a CD ROM or other optical media.

The hard disk drive 327, magnetic disk drive 328, and optical disk drive 330 couple with a hard disk drive interface 332, a magnetic disk drive interface 333, and an optical disk drive interface 334, respectively. The drives and their associated computer-readable media provide non volatile storage of computer-readable instructions, data structures, program modules and other data for the computer 300. It should be appreciated by those skilled in the art that any type of computer-readable media which can store data that is accessible by a computer, such as magnetic cassettes, flash memory cards, digital video disks, Bernoulli cartridges, random access memories (RAMs), read only memories (ROMs), redundant arrays of independent disks (e.g., RAID storage devices) and the like, can be used in the exemplary operating environment.

A plurality of program modules can be stored on the hard disk, magnetic disk 329, optical disk 331, ROM 324, or RAM 325, including an operating system 335, one or more application programs 336, other program modules 337, and program data 338. Programming for implementing one or more processes or method described herein may be resident on any one or number of these computer-readable media.

A user may enter commands and information into computer 300 through input devices such as a keyboard 340 and pointing device 342. Other input devices (not shown) can include a microphone, joystick, game pad, satellite dish, scanner, or the like. These other input devices are often connected to the processing unit 321 through a serial port interface 346 that is coupled to the system bus 323, but can be connected by other interfaces, such as a parallel port, game port, or a universal serial bus (USB). A monitor 347 or other type of display device can also be connected to the system bus 323 via an interface, such as a video adapter 348. The monitor 347 can display a graphical user interface for the user. In addition to the monitor 347, computers typically include other peripheral output devices (not shown), such as speakers and printers.

The computer 300 may operate in a networked environment using logical connections to one or more remote computers or servers, such as remote computer 349. These logical connections are achieved by a communication device coupled to or a part of the computer 300; the invention is not limited to a particular type of communications device. The remote computer 349 can be another computer, a server, a router, a network PC, a client, a peer device or other common network node, and typically includes many or all of the elements described above I/0 relative to the computer 300, although only a memory storage device 350 has been illustrated. The logical connections depicted in FIG. 3 include a local area network (LAN) 351 and/or a wide area network (WAN) 352. Such networking environments are commonplace in office networks, enterprise-wide computer networks, intranets and the internet, which are all types of networks. When used in a LAN-networking environment, the computer 300 is connected to the LAN 351 through a network interface or adapter 353, which is one type of communications device. In some embodiments, when used in a WAN-networking environment, the computer 300 typically includes a modem 354 (another type of communications device) or any other type of communications device, e.g., a wireless transceiver, for establishing communications over the wide-area network 352, such as the internet. The modem 354, which may be internal or external, is connected to the system bus 323 via the serial port interface 346. In a networked environment, program modules depicted relative to the computer 300 can be stored in the remote memory storage device 350 of remote computer, or server 349. It is appreciated that the network connections shown are exemplary and other means of, and communications devices for, establishing a communications link between the computers may be used including hybrid fiber-coax connections, T1-T3 lines, DSL's, OC-3 and/or OC-12, TCP/IP, microwave, wireless application protocol, and any other electronic media through any suitable switches, routers, outlets and power lines, as the same are known and understood by one of ordinary skill in the art.

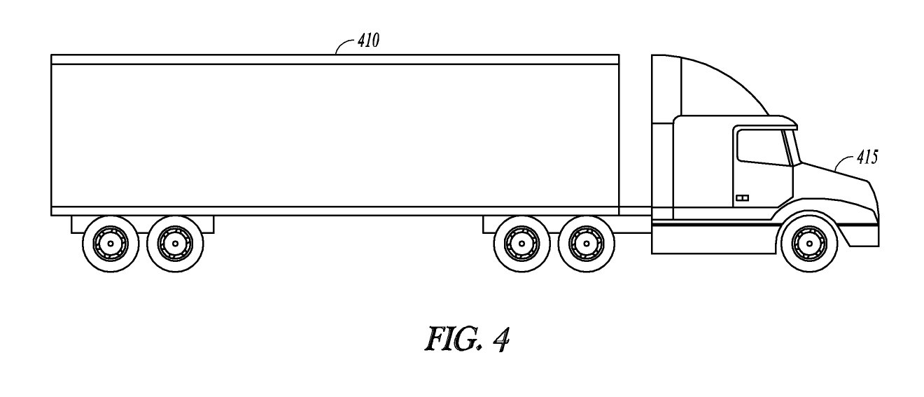

While room 110 may be built on a fixed foundation as part of a building in one embodiment, in further embodiments, the room 110 may be movable as illustrated in block diagram form in FIG. 4. In one embodiment, the room 110 is formed of a shipping container 410 or 18 foot trailer. The shipping container may be moved to various locations as desired by a tractor trailer truck 415, or other form of transport including at least train, plane, and ship. The walls of the shipping container 410 may be used as heat exchangers as described above for room 110.

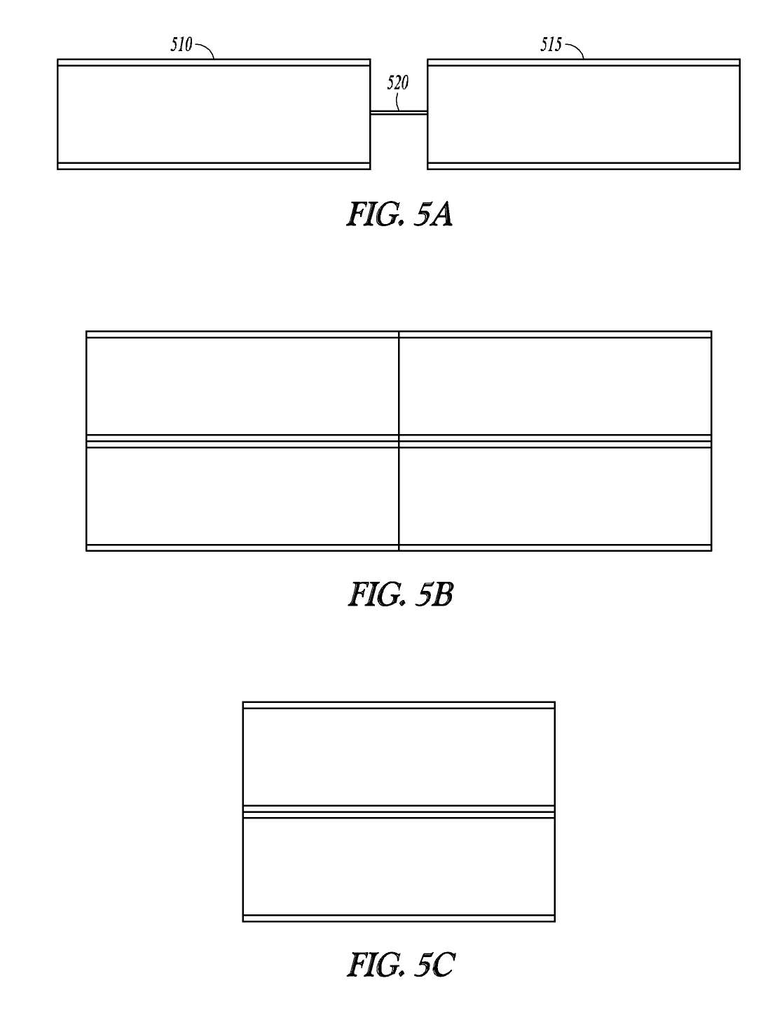

As illustrated in block diagram form in FIG. 5A, multiple containers 510 and 515 may be electrically connected 520 to further containers to create a modular and scalable data center. In further embodiments, the container may also be physically connected in various side by side (top view FIG. 5B), end to end (FIG. 5B), and stacked (side view FIG. 5C) relationships in a manner that still provides adequate cooling by at least one of the side, top, and bottom walls of the container.

What is claimed is:

1. A data center room comprising:
a raised floor having air conditioning equipment beneath the raised floor to provide cooled air to electronic equipment supported by the raised floor;
a ceiling formed as a heat exchanger that conducts heat generated by the electronic equipment; and
an airflow path across and above the ceiling to provide outside air to move heat away from the ceiling.

2. The data center of claim 1 wherein the ceiling comprises corrugated metal.

3. The data center of claim 1 wherein the airflow path runs from the ceiling to outdoor ambient air.

4. The data center of claim 3 wherein the airflow path further includes a warm air inlet to mix with outdoor ambient air.

5. The data center of claim 4 and further including sensors to determine a dew point of air within the room.

6. The data center of claim 5 wherein warm air and outdoor ambient air are mixed in the airflow path as a function of the dew point of air within the room.

7. The data center of claim 1 wherein the ceiling includes fins to dissipate heat generated by the equipment and conducted through the ceiling to the airflow path.

8. The data center of claim 1 wherein the ceiling is air impermeable such that air from the airflow path does not pass through the ceiling.

9. The data center of claim 1 wherein the ceiling comprises metal tiles.

10. The data center of claim 1 wherein the heat exchanger is adapted to reduce a cooling load on the air conditioning equipment.

11. A data center room comprising:
a floor to support electronic equipment;
a cool air inlet to provide cool air to the electronic equipment;
a wall formed as a heat exchanger that conducts heat generated by the electronic equipment from the room; and
an airflow path across and above the wall to provide outside air to move heat away from the wall.

12. The data center of claim 11 wherein the wall comprises corrugated metal.

13. The data center of claim 11 wherein the airflow path runs from the wall to outdoor ambient air.

14. The data center of claim 13 wherein the airflow path further includes a warm air inlet to mix with outdoor ambient air, and wherein the data center further comprises sensors to determine a dew point of air within the room.

15. The data center of claim 14 wherein warm air and outdoor ambient air are mixed in the airflow path as a function of the dew point of air within the room.

16. The data center of claim 11 wherein the ceiling includes fins to dissipate heat generated by the equipment and conducted through the wall to the airflow path.

17. The data center of claim 11 wherein the wall is air impermeable such that air from the airflow path does not pass through the wall into the room.

18. The data center of claim 11 wherein the wall comprises metal tiles.

19. A method comprising:
conducting heat outside a data center room having heat generating electronic equipment via a heat exchanger wall of the room;
providing conditioned cool air to the room; and
moving ambient cool air past the heat exchanger wall to remove heat from the room and reduce a need for conditioned cool air.

20. The method of claim 19 and further comprising mixing warm air with the ambient cool air to keep a temperature of the heat exchanger above a dew point temperature of air in the room.
